(19) United States
(12) Patent Application Publication
(10) Pub. No.: US 2026/0223381 A1
(43) Pub. Date: Jul. 30, 2026

(54) SEMICONDUCTOR DEVICE

(71) Applicant: SAMSUNG ELECTRONICS CO., LTD., Suwon-si (KR)

(72) Inventors: Sang-Il HAN, Suwon-si (KR); Yoonjae KIM, Suwon-si (KR); Jinah KIM, Suwon-si (KR); Seunguk HAN, Suwon-si (KR); Jinwoo HAN, Suwon-si (KR); Seongbin HONG, Suwon-si (KR)

(73) Assignee: SAMSUNG ELECTRONICS CO., LTD., Suwon-si (KR)

(21) Appl. No.: 19/294,977

(22) Filed: Aug. 8, 2025

(30) Foreign Application Priority Data
Jan. 24, 2025 (KR) 10-2025-0011955

(51) Int. Cl. H10D 1/68; H10B 12/00

(52) U.S. Cl. CPC H10D 1/714; H10B 12/482; H10B 12/488; H10B 12/03

(57) ABSTRACT

A semiconductor device includes a substrate, a semiconductor pattern positioned on the substrate and extending in a first direction parallel to an upper surface of the substrate, a word line positioned on the semiconductor pattern and extending in a second direction, which is parallel to the upper surface of the substrate and intersects the first direction, a bit line connected to one end of the semiconductor pattern and extending in a third direction perpendicular to the upper surface of the substrate, a lower electrode comprising a first lower electrode layer covering the other end of the semiconductor pattern and positioned on the other side of the semiconductor pattern, and a second lower electrode layer positioned on the first lower electrode layer, an upper electrode positioned on the lower electrode, and a dielectric layer positioned between the lower electrode and the upper electrode.

### CROSS-REFERENCE TO RELATED APPLICATION

This application claims priority to and the benefit of Korean Patent Application No. 10-2025-0011955 filed with the Korean Intellectual Property Office on January 24, 2025, the entire contents of which are incorporated herein by reference

### BACKGROUND OF THE INVENTION

### Field of the Invention

The present disclosure relates to a semiconductor device.

### Description of the Related Art

Technologies are required to increase the integration density of semiconductor devices. For two-dimensional semiconductor devices, the integration density is mainly determined by the area occupied by the unit memory cell, and this aspect of integration density can be affected by the level of fine pattern formation technology.

However, since the fine pattern formation technology requires expensive equipment, the integration of two-dimensional semiconductor devices is increasing, but is still limited. Accordingly, three-dimensional semiconductor devices having three-dimensionally arranged memory cells are being proposed.

### SUMMARY OF THE INVENTION

The present disclosure attempts to provide semiconductor device capable of manufacturing a highly reliable semiconductor device.

The present disclosure also attempts to provide a semiconductor device having improved electrical characteristics.

An embodiment of the present disclosure provides a semiconductor device comprising: a substrate, a semiconductor pattern positioned on the substrate and extending in a first direction parallel to an upper surface of the substrate, a word line positioned on the semiconductor pattern and extending in a second direction, which is parallel to the upper surface of the substrate and intersects the first direction, a bit line connected to a first end of the semiconductor pattern on a first side and extending in a third direction perpendicular to the upper surface of the substrate, a lower electrode comprising a first lower electrode layer covering a second end of the semiconductor pattern and positioned on a second side of the semiconductor pattern, and a second lower electrode layer positioned on the first lower electrode layer, an upper electrode positioned on the lower electrode, and a dielectric layer positioned between the lower electrode and the upper electrode.

Furthermore, an embodiment of the present disclosure provides a semiconductor device comprising: a substrate, a semiconductor pattern positioned on the substrate and extending in a first direction parallel to an upper surface of the substrate, a word line positioned on the semiconductor pattern and extending in a second direction, which is parallel to the upper surface of the substrate and intersects the first direction, a bit line connected to a first end of the semiconductor pattern on a first side and extending in a third direction perpendicular to the upper surface of the substrate, a lower electrode comprising a first lower electrode layer positioned on a second side of the semiconductor pattern, a second lower electrode layer positioned on the first lower electrode layer, and a third lower electrode layer positioned between the first lower electrode layer and the semiconductor pattern, an upper electrode positioned on the lower electrode, and a dielectric layer positioned between the lower electrode and the upper electrode.

Furthermore, an embodiment of the present disclosure provides a semiconductor device comprising: a substrate, a semiconductor pattern positioned on the substrate and extending in a first direction parallel to an upper surface of the substrate, a word line positioned on the semiconductor pattern and extending in a second direction, which is parallel to the upper surface of the substrate and intersects the first direction, a bit line connected to a first end of the semiconductor pattern on a first side and extending in a third direction perpendicular to the upper surface of the substrate, a lower electrode comprising a first lower electrode layer connected to the second end of the semiconductor pattern and positioned on a second side of the semiconductor pattern, and a second lower electrode layer positioned on the first lower electrode layer and covering the second end of the semiconductor pattern, an upper electrode positioned on the lower electrode, and a dielectric layer positioned between the lower electrode and the upper electrode, wherein the second lower electrode layer comprises a vertical portion positioned between the first lower electrode layer and the semiconductor pattern and extending in the third direction and a horizontal portion extending in the first direction and surrounding an outer side of the first lower electrode layer.

A method for manufacturing a semiconductor device according to an embodiment includes: forming a mask pattern to cover a semiconductor pattern; forming a trench in the mask pattern to expose the semiconductor pattern; etching the semiconductor pattern such that a portion thereof protrudes toward the trench; and forming a first lower electrode layer and a second lower electrode layer on the first lower electrode layer within the trench and on one side of the semiconductor pattern.

In a method for manufacturing a semiconductor device according to an embodiment, before forming the first lower electrode layer on one side of the semiconductor pattern and the second lower electrode layer on the first lower electrode layer, the method may further include forming a third lower electrode layer.

In a method for manufacturing a semiconductor device according to an embodiment, the third lower electrode layer may cover a portion of one side surface and the upper and lower surfaces of the semiconductor pattern.

In a method for manufacturing a semiconductor device according to an embodiment, the step of forming the first lower electrode layer on one side of the semiconductor pattern and the second lower electrode layer on the first lower electrode layer may include: forming a second lower electrode material layer; forming a first lower electrode material layer on the second lower electrode material layer; and patterning the first and second lower electrode material layers to form the first and second lower electrode layers.

In a method for manufacturing a semiconductor device according to an embodiment, the second lower electrode layer may cover a portion of one side surface and the upper and lower surfaces of the semiconductor pattern.

In a method for manufacturing a semiconductor device according to an embodiment, the step of forming the first lower electrode layer on one side of the semiconductor pattern and the second lower electrode layer on the first lower electrode layer may include: forming a second lower electrode material layer; patterning the second lower electrode material layer to form the second lower electrode layer; forming a first lower electrode material layer inside the second lower electrode layer; and patterning the first lower electrode material layer to form the first lower electrode layer.

In a method for manufacturing a semiconductor device according to an embodiment, the first lower electrode layer may be in contact with the semiconductor pattern, and the second lower electrode layer may cover a portion of the upper and lower surfaces of the semiconductor pattern.

In a method for manufacturing a semiconductor device according to an embodiment, before forming the first lower electrode layer on one side of the semiconductor pattern and the second lower electrode layer on the first lower electrode layer, the method may further include forming a silicide layer.

In a method for manufacturing a semiconductor device according to an embodiment, the first lower electrode layer may be formed such that its length in a first direction DR1 is shorter than the length of the second lower electrode layer in the first direction DR1.

In a method for manufacturing a semiconductor device according to an embodiment, one side surface of the first lower electrode layer may be positioned on the same plane as one side surface of the second lower electrode layer.

According to embodiments, a semiconductor device with high reliability may be provided.

Further, according to embodiments, a semiconductor device with improved electrical characteristics may be provided.

### BRIEF DESCRIPTION OF THE DRAWINGS

FIG. 1 is a perspective view schematically illustrating a semiconductor device according to one embodiment.

FIG. 2 is a cross-sectional view of a semiconductor device according to one embodiment.

FIG. 3 is an enlarged view of area A of FIG. 2.

FIG. 4, FIG. 5, FIG. 6, FIG. 7, FIG. 8, FIG. 9, FIG. 10, FIG. 11 and FIG. 12 are drawings illustrating a part of a method for manufacturing a semiconductor device according to one embodiment.

FIG. 13 is a cross-sectional view of a semiconductor device according to another embodiment.

FIG. 14 and FIG. 15 are drawings showing a part of a method for manufacturing a semiconductor device according to another embodiment of FIG. 13.

FIG. 16 is a cross-sectional view of a semiconductor device according to another embodiment.

FIG. 17, FIG. 18, FIG. 19, and FIG. 20 are drawings showing a part of a method for manufacturing a semiconductor device according to another embodiment of FIG. 16.

FIG. 21 is a cross-sectional view of a semiconductor device according to another embodiment.

FIG. 22, FIG. 23, FIG. 24, FIG. 25 and FIG. 26 are drawings showing a part of a method for manufacturing a semiconductor device according to another embodiment of FIG. 21.

FIG. 27 is a cross-sectional view of a semiconductor device according to another embodiment.

FIG. 28, FIG. 29, FIG. 30 and FIG. 31 are drawings showing a part of a method for manufacturing a semiconductor device according to another embodiment of FIG. 27.

FIG. 32 is a cross-sectional view of a semiconductor device according to another embodiment.

FIG. 33, FIG. 34, FIG. 35, FIG. 36 and FIG. 37 are drawings showing a part of a method for manufacturing a semiconductor device according to another embodiment of FIG. 32.

### DETAILED DESCRIPTION OF THE EMBODIMENTS

Hereinafter, various embodiments of the present invention will be described in detail with reference to the attached drawings so that a person having ordinary skill in the art to which the present invention pertains can easily implement the invention. The present invention may be embodied in many different forms and is not limited to the embodiments described herein.

In order to clearly explain the present invention, parts irrelevant to the description are omitted, and the same reference numerals are used for identical or similar components throughout the specification.

In addition, the size and thickness of each component shown in the drawing are arbitrarily shown for convenience of explanation, so the present invention is not necessarily limited to what is shown. In the drawings, the thickness of layers, films, panels, regions, etc., are exaggerated for clarity. And in the drawing, for convenience of explanation, the thickness of some layers and areas is exaggerated.

Also, when we say that a part, such as a layer, membrane, region, or plate, is "over" or "on" another part, this includes not only cases where it is "directly over" the other part, but also cases where there are other parts in between. In contrast, when an element is referred to as being “directly on” another element, there are no intervening elements present. Also, being "above" or "on" a reference part means being located above or below the reference part, and does not necessarily mean being located "above" or "on" the opposite direction of gravity.

Additionally, throughout the specification, whenever a part is said to "include" a component, this does not mean that it excludes other components, but rather that it may include other components, unless otherwise specifically stated.

Additionally, throughout the specification, when we say "in plan", we mean when the target portion is viewed from above, and when we say "in cross section", we mean when the target portion is viewed from the side in a cross-section cut vertically.

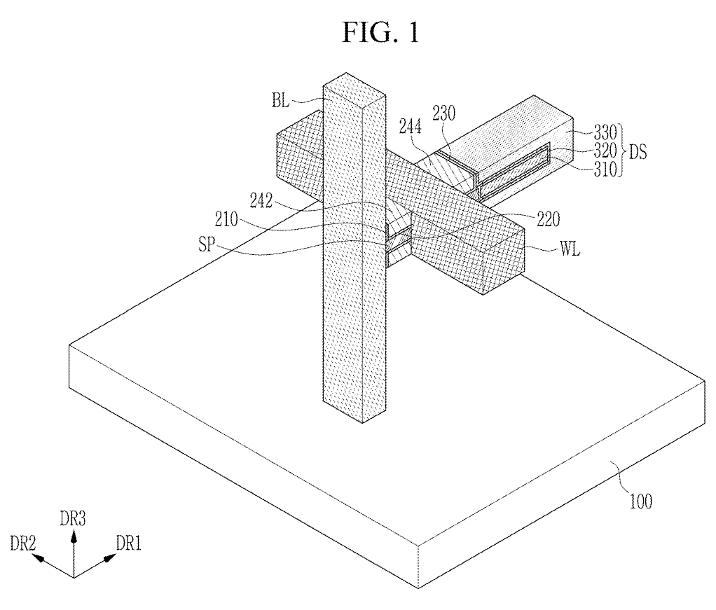

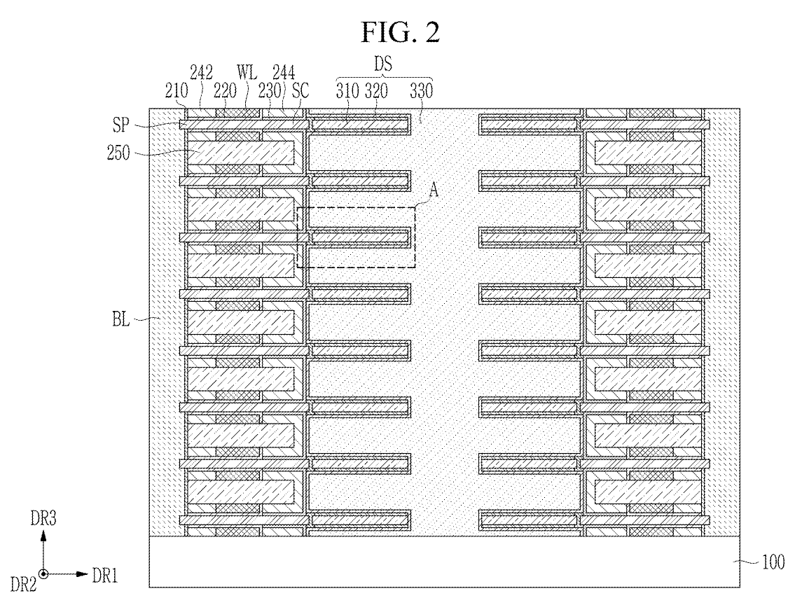

FIG. 1 is a perspective view schematically illustrating a semiconductor device according to one embodiment. FIG. 2 is a cross-sectional view of a semiconductor device according to one embodiment.

Referring to FIG. 1 and FIG. 2, a semiconductor device according to one embodiment may include a substrate 100, a bit line BL, a semiconductor pattern SP, and a word line WL.

For convenience of explanation, FIG. 1 illustrates one bit line BL, one word line WL, one semiconductor pattern SP, and one data storage element DS, and some of the insulating layers are omitted.

The substrate 100 may be, for example, a silicon substrate, a germanium substrate, or a silicon-germanium substrate. The substrate 100 may have a shape extending in a first direction DR1 and a second direction DR2. Here, the second direction DR2 may be a direction intersecting the first direction DR1. For example, the first direction DR1 and the second direction DR2 can be orthogonal to each other. For example, the first direction DR1 and the second direction DR2 may be directions parallel to the upper surface of the substrate 100. Although not shown, additional peripheral circuitry may be provided on the substrate 100.

The bit line BL extending in a third direction DR3 may be positioned on the upper surface of the substrate 100. The bit line BL may have a shape extending in a third direction DR3 that is perpendicular to the upper surface of the substrate 100. Here, the third direction DR3 may be a direction intersecting the first direction DR1 and the second direction DR2. For example, the second direction DR2 and the third direction DR3 can be orthogonal to each other. The third direction DR3 and the first direction DR1 can be orthogonal to each other. For example, the third direction DR3 may be a direction perpendicular to the upper surface of the substrate 100.

The bit line BL may include a conductive material. The conductive material can be, for example, one of a doped semiconductor material such as doped silicon (doped Si) or doped germanium (doped Ge), a conductive metal nitride such as titanium nitride (TiN) or tantalum nitride (TaN), a metal such as tungsten (W), titanium (Ti), or tantalum (Ta), or a metal-semiconductor compound such as tungsten silicide (WSiₓ), cobalt silicide (CoSiₓ), or titanium silicide (TiSiₓ).

In FIG. 1, one bit line BL is positioned on the substrate 100, and in FIG. 2, two bit lines BL are positioned on the substrate 100, but the present invention is not limited thereto. The plurality of bit lines BL can be positioned spaced apart from each other in the first direction DR1 and the second direction DR2 on the substrate 100.

The semiconductor pattern SP can be positioned on the substrate 100. The semiconductor pattern SP may have a shape extending in the first direction DR1. For example, the semiconductor pattern SP may have a bar shape extending in the first direction DR1. The semiconductor pattern SP may partially protrude from a second insulating layer 230 toward the data storage element DS.

The semiconductor pattern SP can be connected to the bit line BL. One end of the semiconductor pattern SP can be connected to the bit line BL. The semiconductor pattern SP can be positioned to penetrate a first insulating layer 210. For example, one end of the semiconductor pattern SP can be capped by the bit line BL. However, it is not limited to this. For example, one end of the semiconductor pattern SP may be in contact with one end of the bit line BL.

For example, the semiconductor patterns SP may include silicon (Si), germanium (Ge), or silicon-germanium (SiGe). Each of the semiconductor patterns SP may include a channel region, a first impurity region, and a second impurity region.

The first impurity region and the second impurity region may represent regions in which the semiconductor pattern SP is doped with impurities. The first impurity region and the second impurity region can have a conductivity type of n-type or p-type. For example, the first impurity region and the second impurity region may be positioned at each end of the semiconductor pattern SP.

One end of the semiconductor pattern SP can be connected to the bit line BL. The semiconductor pattern SP may be connected to the bit line BL in a form in which a portion of the semiconductor pattern SP protrudes toward inside of the bit line BL, but is not limited thereto. For example, the side surface of one end of the semiconductor pattern SP may not protrude and may be in contact with the side surface of the bit line BL. By way of example, one end of the semiconductor pattern SP may be referred to as a first end. The side where one end of the semiconductor pattern SP is located may be referred to as a first side.

The other end of the semiconductor pattern SP can be connected to the data storage element DS. For example, the first impurity region of the semiconductor pattern SP may be connected to the bit line BL, and the second impurity region of the semiconductor pattern SP may be connected to the data storage element DS. The channel region may be positioned between the first impurity region and the second impurity region. By way of example, the other end of the semiconductor pattern SP may be referred to as a second end. The side where the other end of the semiconductor pattern SP is located may be referred to as a second side.

The plurality of semiconductor patterns SP may be positioned on the substrate 100, and the plurality of semiconductor patterns SP may be stacked so as to be spaced apart from each other along the third direction DR3. For example, the plurality of semiconductor patterns SP connected to one bit line BL can be positioned to be spaced apart from each other along the third direction DR3. Additionally, the plurality of semiconductor patterns SP may be positioned to be spaced apart from each other in the first direction DR1 and the second direction DR2 along the bit lines BL that are positioned to be spaced apart from each other in the first direction DR1 and the second direction DR2.

The word line WL can be positioned on the semiconductor pattern SP. The word line WL may have a shape extending along the second direction DR2. For example, the word line WL may have a bar shape extending along the second direction.

For example, one word line WL may be positioned to surround a portion of the semiconductor pattern SP. However, the invention is not limited thereto, and for example, a pair of word lines may be positioned respectively above and below the semiconductor pattern SP. The plurality of word lines WL may be positioned on the substrate 100, and the plurality of word lines WL may be stacked while being spaced apart from each other in a third direction DR3.

The word line WL may include a conductive material. The conductive material can be any one of a semiconductor material, a conductive metal nitride, a metal, or a metal-semiconductor compound.

A semiconductor device according to one embodiment may further include the first insulating layer 210, a gate insulating pattern 220, the second insulating layer 230, a first spacer 242, a second spacer 244, and an interlayer insulating layer 250.

The first insulating layer 210 may be placed on one side surface of the bit line BL. The first insulating layer 210 may be positioned between the bit line BL and the first spacer 242. Additionally, the first insulating layer 210 may be positioned between the bit line BL and the interlayer insulating layer 250.

The gate insulating pattern 220 may be placed between the word line WL and the semiconductor pattern SP. The semiconductor pattern SP and the word line WL can be positioned to be spaced apart in the third direction DR3 with the gate insulating pattern 220 interposed therebetween. The gate insulating pattern 220 may be further positioned between the first spacer 242 and the semiconductor pattern SP. Additionally, by way of example, the gate insulating pattern 220 may be further positioned between the word line WL and the second spacer 244. For example, the gate insulating pattern 220 may have an “L” shape in the cross-section in the first direction DR1 and the third direction DR3, but is not limited thereto. For example, the gate insulating pattern 220 may have a straight line shape extending along the semiconductor pattern SP.

The gate insulating pattern 220 may include an insulating material. The gate insulating pattern 220 may include a silicon oxide film, a silicon oxynitride film, a high-k dielectric film having a higher dielectric constant than the silicon oxide film, or a combination thereof. Here, the high-k dielectric film can be made of a metal oxide or a metal oxide nitride. For example, the high-k dielectric film that can be used as the gate insulating pattern 220 may include, but is not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or a combination thereof.

The second insulating layer 230 may be positioned between the second spacer 244 and the semiconductor pattern SP. The second insulating layer 230 may be positioned between the second spacer 244 and the data storage element DS. For example, the second insulating layer 230 may have an “L” shape in the cross-section in the first direction DR1 and the third direction DR3, but is not limited thereto.

The first spacer 242 may be positioned between the word line WL and the bit line BL. The first spacer 242 may have a shape that surrounds a portion of the semiconductor pattern SP between the word line WL and the bit line BL. The first spacer 242 may be positioned between the first insulating layer 210 and the word line WL.

The second spacer 244 may be positioned between the word line WL and the data storage element DS. The first spacer 242 and the second spacer 244 can be positioned on both sides of the word line WL. The second spacer 244 may have a form that surrounds a portion of the semiconductor pattern SP between the word line WL and the data storage element DS. The second spacer 244 may be positioned between the second insulating layer 230 and the interlayer insulating layer 250.

The first insulating layer 210, the second insulating layer 230, the first spacer 242, and the second spacer 244 may include an insulating material. The first insulating layer 210, the second insulating layer 230, the first spacer 242, and the second spacer 244 may include the same insulating material. Alternatively, at least one of the first insulating layer 210, the second insulating layer 230, the first spacer 242, and the second spacer 244 may include different insulating materials. For example, the first insulating layer 210, the second insulating layer 230, the first spacer 242, and the second spacer 244 may include at least one of silicon oxide (SiO), silicon nitride (SiN), and silicon oxynitride (SiON), but are not limited thereto. The first insulating layer 210, the second insulating layer 230, the first spacer 242, and the second spacer 244 may be formed simultaneously or may be formed separately.

The interlayer insulating layer 250 may be placed between the plurality of semiconductor patterns SP. The plurality of semiconductor patterns SP may be positioned to be spaced apart in the third direction DR3, and the interlayer insulating layer 250 may be positioned between the plurality of semiconductor patterns SP spaced apart in the third direction DR3.

The interlayer insulating layer 250 may be positioned over the word line WL. The interlayer insulating layer 250 may be positioned over the first spacer 242. Additionally, the interlayer insulating layer 250 may be positioned between the plurality of word lines WL. The plurality of word lines WL may be positioned to be spaced apart in the third direction DR3, and the interlayer insulating layer 250 may be positioned between the plurality of word lines WL spaced apart in the third direction DR3. The interlayer insulating layer 250 may be positioned between the second spacer 244 and the bit line BL. The interlayer insulating layer 250 may be positioned between the second spacer 244 and the first insulating layer 210. For example, one side surface of the interlayer insulating layer 250 may be in contact with the first insulating layer 210, and the other side surface of the interlayer insulating layer 250 may be in contact with the second spacer 244.

The interlayer insulating layer 250 may include an insulating material. By way of example, the interlayer insulating layer 250 may include at least one of silicon oxide (SiO), silicon nitride (SiN), and silicon oxynitride (SiON), but is not limited thereto.

The semiconductor device according to one embodiment may include the data storage element DS.

A data storage element DS can be connected to the semiconductor pattern SP. The other end of the semiconductor pattern SP can be connected to the data storage element DS. The plurality of data storage elements DS can be positioned to be stacked in the third direction DR3.

The data storage element DS may include a lower electrode 310, a dielectric layer 320, and an upper electrode 330.

The lower electrode 310 can be connected to the other end of the semiconductor pattern SP. One end of the lower electrode 310 can be connected to the semiconductor pattern SP. The lower electrode 310 can cover a portion of the other side surface and the upper and lower surfaces of the semiconductor pattern SP. The lower electrode 310 may have a shape that surrounds the other end of the semiconductor pattern SP. The lower electrode 310 can be positioned at substantially the same level as the semiconductor pattern SP. The lower electrode 310 can be aligned parallel to the semiconductor pattern SP in the first direction DR1.

The lower electrode 310 may have a shape extending in the first direction DR1. The lower electrode 310 may have a bar or pillar shape extending in the first direction DR1, but is not limited thereto. For example, the lower electrode 310 may have a cylinder shape with a hollow center. The width of the lower electrode 310 in the second direction DR2 or the third direction DR3 may be substantially the same as the width of the semiconductor pattern SP in the second direction DR2 or the third direction DR3, but is not limited thereto. For example, the width of the lower electrode 310 in the second direction DR2 or the third direction DR3 may be different from the width of the semiconductor pattern SP in the second direction DR2 or the third direction DR3.

The lower electrode 310 may include a first lower electrode layer 311, a second lower electrode layer 312, and a third lower electrode layer 313, which will be described in detail later.

The dielectric layer 320 may be positioned on the lower electrode 310. The dielectric layer 320 may be positioned between the lower electrode 310 and the upper electrode 330. The dielectric layer 320 can cover the upper, lower, and side surfaces of the lower electrode 310. For example, the side of the lower electrode 310 may mean a surface that is perpendicular to the upper surface of the substrate 100. Additionally, the dielectric layer 320 may cover a portion of the other side surface of the lower electrode 310. Here, the other side surface of the lower electrode 310 may mean a surface opposite to one side surface of the lower electrode 310 where the lower electrode 310 and the semiconductor pattern SP are connected. The other side surface of the lower electrode 310 may be covered by the dielectric layer 320. The dielectric layer 320 can be conformally placed on the lower electrode 310. The dielectric layer 320 can be placed on the second insulating layer 230. The first spacer 242 and the second spacer 244 may be placed on the interlayer insulating layer 250, the second insulating layer 230 may be placed on the second spacer 244, and the dielectric layer 320 may be placed on the second insulating layer 230. For example, the second spacer 244 may be placed on a side surface of the interlayer insulating layer 250.

The dielectric layer 320 may include an insulating material. The dielectric layer 320 may include a silicon oxide film, a silicon oxynitride film, a high-k dielectric film having a higher dielectric constant than the silicon oxide film, or a combination thereof. The high-k dielectric film can be made of a metal oxide or a metal oxide nitride. For example, high-k dielectric films usable as the dielectric layer 320 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or combinations thereof, but are not limited thereto.

The upper electrode 330 may be positioned on the dielectric layer 320. The upper electrode 330 can fill the space between the plurality of lower electrodes 310. The data storage elements DS of multiple layers stacked in the third direction DR3 can share one upper electrode 330.

The upper electrode 330 may include a conductive material. The upper electrode 330 may include, for example, at least one of a metal material such as titanium (Ti), tantalum (Ta), tungsten (W), copper (Cu), aluminum (Al), platinum (Pt), iridium (Ir), or ruthenium (Ru), a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

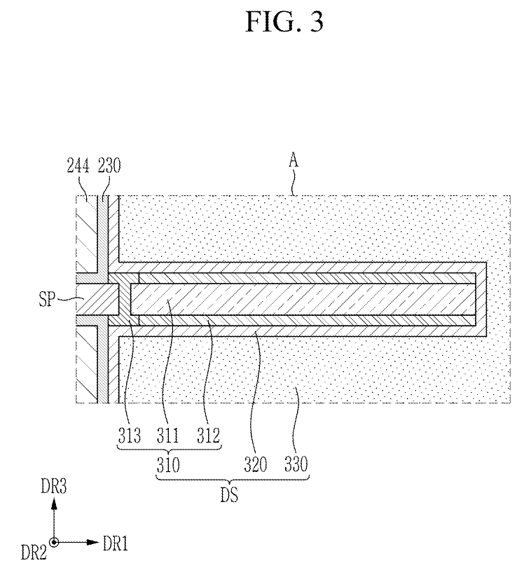

FIG. 3 is an enlarged view of area A of FIG. 2.

Referring to FIG. 3, the semiconductor pattern SP may be positioned to protrude in the first direction DR1 from the second spacer 244 and the second insulating layer 230. The other end of the semiconductor pattern SP can be connected to the data storage element DS. The data storage element DS may include the lower electrode 310, the dielectric layer 320, and the upper electrode 330.

The lower electrode 310 may include the first lower electrode layer 311, the second lower electrode layer 312, and the third lower electrode layer 313.

The first lower electrode layer 311 may be positioned on the other side of the semiconductor pattern SP. The first lower electrode layer 311 can be positioned at substantially the same level as the semiconductor pattern SP. The first lower electrode layer 311 can be aligned parallel to the semiconductor pattern SP in the first direction DR1. One side surface of the first lower electrode layer 311 can be in contact with the third lower electrode layer 313, and the dielectric layer 320 can be positioned on the other side surface of the first lower electrode layer 311.

The first lower electrode layer 311 may have a shape extending in the first direction DR1. For example, the first lower electrode layer 311 may have a bar shape, but is not limited thereto. The other side surface of the first lower electrode layer 311 may be positioned on the same plane as the other side surface of the second lower electrode layer 312.

The first lower electrode layer 311 may include a conductive material. The first lower electrode layer 311 may include a low-resistance metal. For example, the first lower electrode layer 311 may include a low-resistance metal such as titanium (Ti), tantalum (Ta), tungsten (W), copper (Cu), aluminum (Al), platinum (Pt), iridium (Ir), or ruthenium (Ru).

Additionally, the first lower electrode layer 311 may include at least one of a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

The second lower electrode layer 312 may be positioned on the other side of the semiconductor pattern SP. The second lower electrode layer 312 can be positioned on top of the first lower electrode layer 311. One side surface of the second lower electrode layer 312 can be in contact with the third lower electrode layer 313, and the dielectric layer 320 can be positioned on the other side surface of the second lower electrode layer 312. The other side surface of the second lower electrode layer 312 may be positioned on the same plane as the other side surface of the first lower electrode layer 311.

The second lower electrode layer 312 can be positioned to overlap the first lower electrode layer 311 in the second direction DR2 and the third direction DR3. For example, the second lower electrode layer 312 may be positioned so as not to overlap the first lower electrode layer 311 in the first direction DR1, but is not limited thereto. The second lower electrode layer 312 can be conformally placed on the first lower electrode layer 311. The length of the second lower electrode layer 312 in the first direction DR1 may be shorter than the length of the first lower electrode layer 311 in the first direction DR1, but is not limited thereto. In some embodiments, the length of the second lower electrode layer 312 in the first direction DR1 may be longer than the length of the first lower electrode layer 311 in the first direction DR1. The second lower electrode layer 312 may be positioned apart from the other end of the semiconductor pattern SP, but is not limited thereto. In some embodiments, the second lower electrode layer 312 may be positioned to surround one end of the semiconductor pattern SP. For example, the second lower electrode layer 312 may have a hollow column shape with both sides open in the first direction DR1, but is not limited thereto. The first lower electrode layer 311 can be positioned in the inner empty space of the second lower electrode layer 312. The outer side of the second lower electrode layer 312 may be surrounded by the dielectric layer 320.

The second lower electrode layer 312 may have a shape extending in the first direction DR1. The second lower electrode layer 312 may have a shape that surrounds the outer side of the first lower electrode layer 311. The second lower electrode layer 312 may not cover the other side surface of the first lower electrode layer 311, but is not limited thereto. In some embodiments, the second lower electrode layer 312 may cover the other side surface of the first lower electrode layer 311.

The second lower electrode layer 312 may include a conductive material. The second lower electrode layer 312 may include a high-work function material. The second lower electrode layer 312 may include a conductive material among high-work function materials. For example, the second lower electrode layer 312 may include at least one of a metal, such as tungsten (W), platinum (Pt), gold (Au), nickel (Ni), palladium (Pd), ruthenium (Ru), iridium (Ir), cobalt (Co), and molybdenum (Mo), or an oxide or nitride thereof.

The third lower electrode layer 313 may be positioned on the other side of the semiconductor pattern SP. The third lower electrode layer 313 may be positioned between the first lower electrode layer 311 and the semiconductor pattern SP. Additionally, the third lower electrode layer 313 may be positioned between the second insulating layer 230 and the second lower electrode layer 312. The third lower electrode layer 313 may be surrounded by the dielectric layer 320.

The third lower electrode layer 313 can cover the other end of the semiconductor pattern SP. The third lower electrode layer 313 can cover the other side surface of the semiconductor pattern SP. The third lower electrode layer 313 can be positioned to surround the other end of the semiconductor pattern SP. For example, the third lower electrode layer 313 may cover a portion of the other side surface and upper and lower surfaces of the semiconductor pattern SP. The third lower electrode layer 313 may have a shape that surrounds the other end of the semiconductor pattern SP. The third lower electrode layer 313 can be positioned to surround one end of the first lower electrode layer 311. For example, the third lower electrode layer 313 may cover one side surface and a portion of the upper and lower surfaces of the first lower electrode layer 311. The third lower electrode layer 313 can simultaneously cover the end of the semiconductor pattern SP and the end of the first lower electrode layer 311. The semiconductor pattern SP and the first lower electrode layer 311 can be positioned spaced apart from each other with the third lower electrode layer 313 interposed therebetween. The third lower electrode layer 313 may have an H-shaped cross-section when viewed in the second direction DR2, but is not limited thereto. The third lower electrode layer 313 may include internal spaces positioned on opposite sides in the first direction DR1. The end of a semiconductor pattern SP may be positioned in one internal space of the third lower electrode layer 313, and the first lower electrode layer 311 may be positioned in the other internal space of the third lower electrode layer 313.

The third lower electrode layer 313 can be positioned to overlap the semiconductor pattern SP in the first direction DR1. The third lower electrode layer 313 can be positioned to overlap the first lower electrode layer 311 in the first direction DR1. The third lower electrode layer 313 can be positioned to overlap the other end of the semiconductor pattern SP in the second direction DR2 and the third direction DR3. The third lower electrode layer 313 can be positioned to overlap one end of the first lower electrode layer 311 in the second direction DR2 and the third direction DR3.

The third lower electrode layer 313 can electrically connect the semiconductor pattern SP and the first lower electrode layer 311. Additionally, the third lower electrode layer 313 can electrically connect the semiconductor pattern SP and the second lower electrode layer 312.

The third lower electrode layer 313 can play a role in reducing the contact resistance between the first lower electrode layer 311 and the semiconductor pattern SP. The third lower electrode layer 313 may include a conductive material. For example, the third lower electrode layer 313 may include polysilicon.

The dielectric layer 320 can be conformally positioned on the first lower electrode layer 311, the second lower electrode layer 312, and the third lower electrode layer 313. The dielectric layer 320 can cover the other side surface of the first lower electrode layer 311. The dielectric layer 320 may be positioned on the second lower electrode layer 312. The dielectric layer 320 may be positioned on the third lower electrode layer 313.

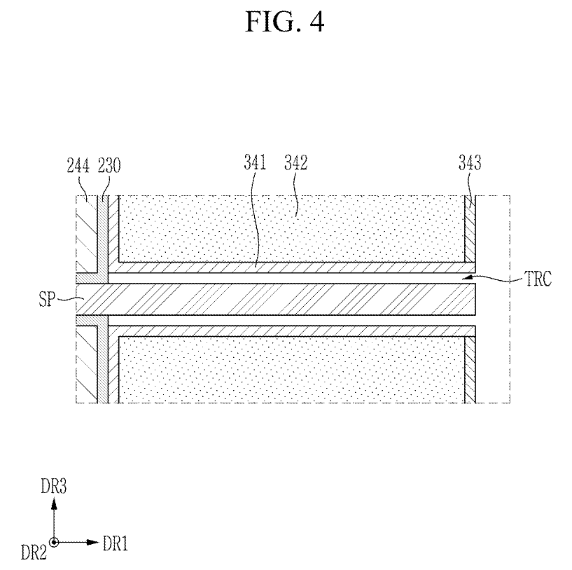

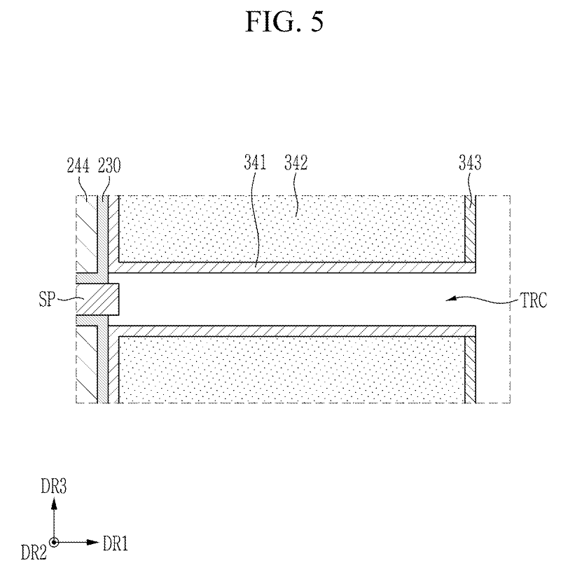

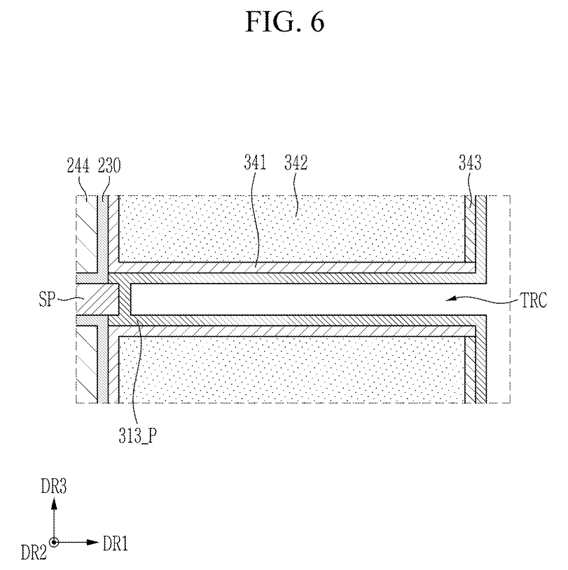

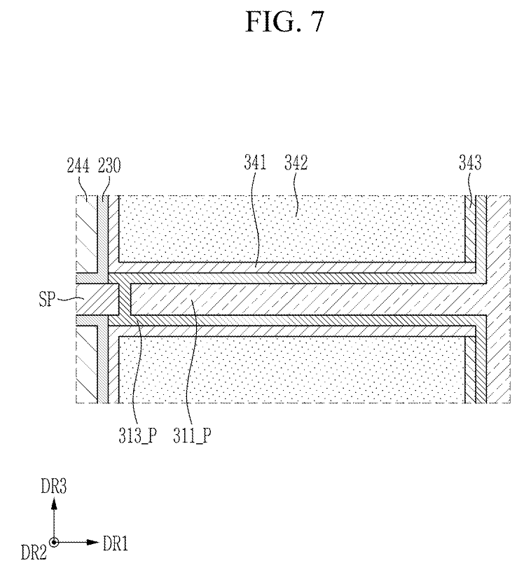

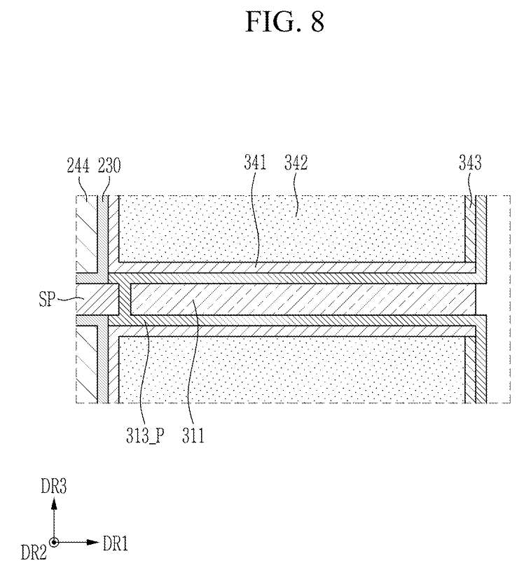

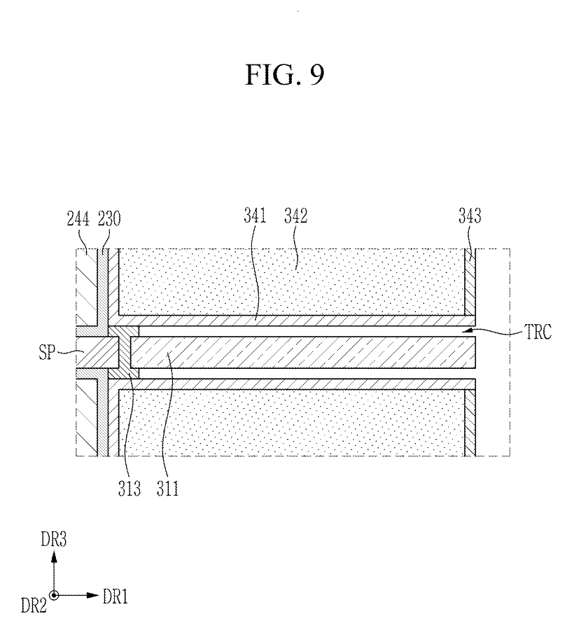

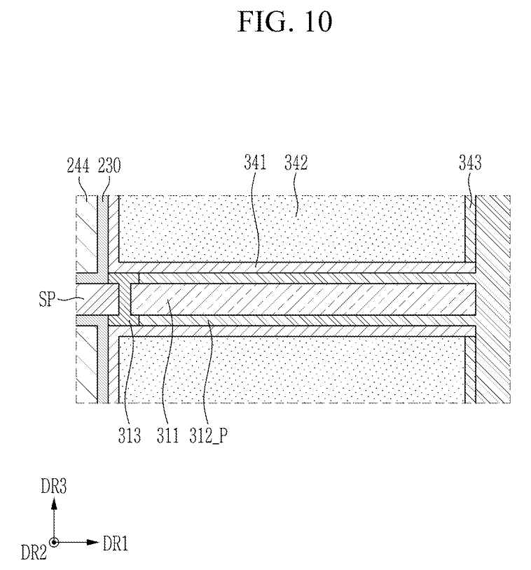

FIG. 4 to FIG. 12 are drawings illustrating a part of a method for manufacturing a semiconductor device according to one embodiment.

Referring to FIG. 4, the second spacer 244 and the second insulating layer 230 may be positioned on the semiconductor pattern SP. The semiconductor pattern SP may be positioned to protrude in the first direction DR1 from the second spacer 244 and the second insulating layer 230.

A trench TRC may be positioned on a first mask pattern 341, a second mask pattern 342, and a third mask pattern 343. The first mask pattern 341, the second mask pattern 342, and the third mask pattern 343 can be positioned to surround the trench TRC. In other words, the trench TRC may be positioned between the plurality of first mask patterns 341, the plurality of second mask patterns 342, and the plurality of third mask patterns 343. The trench TRC may mean an empty space and may have a shape extending in the first direction DR1.

After forming the first mask pattern 341, the second mask pattern 342, the third mask pattern 343, and an additional mask pattern on the semiconductor pattern SP, a process of forming the trench TRC on the mask patterns can be performed. The semiconductor pattern SP can be exposed through a process of forming the trench TRC.

The semiconductor pattern SP can be positioned to extend along the first direction DR1 within the trench TRC. The other side surface of the semiconductor pattern SP may be exposed to the outside. The upper and lower surfaces of the semiconductor pattern SP may be exposed to the outside by the trench TRC.

The first mask pattern 341, the second mask pattern 342, and the third mask pattern 343 may be positioned on the semiconductor pattern SP.

Some of the first mask patterns 341 may be positioned to contact the second insulating layer 230, and other parts of the first mask patterns 341 may have a form extending in the first direction DR1 and may be positioned parallel to the semiconductor pattern SP. The first mask pattern 341 can be positioned to be spaced apart from the semiconductor pattern SP by a certain distance. The first mask pattern 341 can be positioned to surround the semiconductor pattern SP while being spaced apart from each other. Additionally, the first mask pattern 341 may be positioned to surround the trench TRC. The first mask pattern 341 may be positioned between the second insulating layer 230 and the second mask pattern 342. Additionally, the first mask pattern 341 may be positioned between the semiconductor pattern SP and the second mask pattern 342. Additionally, the first mask pattern 341 may be positioned between the semiconductor pattern SP and the third mask pattern 343.

The second mask pattern 342 can be positioned on the first mask pattern 341. The second mask pattern 342 can be positioned to be spaced apart from the semiconductor pattern SP with the first mask pattern 341 and the trench TRC interposed therebetween. The second mask pattern 342 can be positioned to surround the semiconductor pattern SP while being spaced apart from each other. Additionally, the second mask pattern 342 may be positioned to surround the trench TRC.

The third mask pattern 343 can be positioned on the first mask pattern 341 and the second mask pattern 342. The third mask pattern 343 may be positioned on one end of the first mask pattern 341 and the second mask pattern 342. One side surface of the third mask pattern 343 may be exposed. For example, the third mask pattern 343 may be positioned to surround the semiconductor pattern SP while being spaced apart from each other. Additionally, the third mask pattern 343 may be positioned to surround the trench TRC.

The first mask pattern 341, the second mask pattern 342, and the third mask pattern 343 may include an insulating material. For example, the first mask pattern 341, the second mask pattern 342, and the third mask pattern 343 may include at least one of silicon oxide (SiO), silicon nitride (SiN), and silicon oxynitride (SiON), but are not limited thereto.

Next, referring to FIG. 5, a portion of the semiconductor pattern SP can be removed. The semiconductor pattern SP from which a portion has been removed may partially protrude in the first direction DR1 from the second spacer 244 and the second insulating layer 230. A portion of the semiconductor pattern SP may protrude in a direction toward the trench TRC. An etching process can be used to remove the semiconductor pattern SP.

Next, referring to FIG. 6, a third lower electrode material layer 313_Pcan be formed within the trench TRC. The third lower electrode material layer 313_P can fill part of the trench TRC. The third lower electrode material layer 313_P can be conformally formed on the third mask pattern 343, the first mask pattern 341, and the semiconductor pattern SP. The third lower electrode material layer 313_P can cover the other end of the semiconductor pattern SP.

The third lower electrode material layer 313_P may include a conductive material. For example, the third lower electrode material layer 313_P may include polysilicon.

Next, referring to FIG. 7, a first lower electrode material layer 311_Pcan be formed on the third lower electrode material layer 313_P. The first lower electrode material layer 311_P can fill the trench TRC.

The first lower electrode material layer 311_P may include a conductive material. The first lower electrode material layer 311_P may include a low-resistance metal. For example, the first lower electrode material layer 311_P may include a low-resistance metal such as titanium (Ti), tantalum (Ta), tungsten (W), copper (Cu), aluminum (Al), platinum (Pt), iridium (Ir), or ruthenium (Ru).

Additionally, the first lower electrode material layer 311_P may include at least one of a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

Next, referring to FIG. 8, a patterning process of the first lower electrode material layer 311_P can be performed. A portion of the first lower electrode material layer 311_P may be removed to form the first lower electrode layer 311. A portion of the first lower electrode material layer 311_P positioned on the third mask pattern 343 can be removed. Additionally, a portion of the first lower electrode material layer 311_P positioned within the trench TRC or a portion overlapping the trench TRC in the first direction DR1 can be removed. The third lower electrode material layer 313_P can be positioned to surround the first lower electrode layer 311.

For example, the outer side of the first lower electrode layer 311 may be positioned on the same plane as the side of the third mask pattern 343. An etch back process may be used to remove part of the first lower electrode material layer 311_P.

Next, referring to FIG. 9, a patterning process of the third lower electrode material layer 313_P can be performed. A portion of the third lower electrode material layer 313_P may be removed to form the third lower electrode layer 313. A portion of the third lower electrode material layer 313_P positioned above the third mask pattern 343 can be removed. Additionally, some of the portions of the third lower electrode material layer 313_P positioned within the trench TRC may be removed.

As a portion of the third lower electrode material layer 313_P is removed, a void may be formed within the trench TRC, and a portion of the first lower electrode layer 311 may be exposed to the outside.

The third lower electrode layer 313 can cover a portion of the other side surface and upper and lower surfaces of the semiconductor pattern SP. Additionally, the third lower electrode layer 313 can cover one side surface and a portion of the upper and lower surfaces of the first lower electrode layer 311.

Next, referring to FIG. 10, a second lower electrode material layer 312_P can be formed within the trench TRC. The second lower electrode material layer 312_P can be formed on the third mask pattern 343, the first mask pattern 341, the first lower electrode layer 311, and the third lower electrode layer 313. The second lower electrode material layer 312_P can be positioned to surround the first lower electrode layer 311.

The second lower electrode material layer 312_P may include a conductive material. The second lower electrode material layer 312_P may include a high-work function material. For example, the second lower electrode material layer 312_P may include at least one of a metal, such as tungsten (W), platinum (Pt), gold (Au), nickel (Ni), palladium (Pd), ruthenium (Ru), iridium (Ir), cobalt (Co), and molybdenum (Mo), or an oxide or nitride thereof.

Next, referring to FIG. 11, a patterning process of the second lower electrode material layer 312_P can be performed. A portion of the second lower electrode material layer 312_P may be removed to form the second lower electrode layer 312. A portion of the second lower electrode material layer 312_P positioned on the third mask pattern 343 can be removed. Additionally, some of the portions of the second lower electrode material layer 312_P that overlap with the trench TRC in the first direction DR1 may be removed.

One side surface of the first lower electrode layer 311, one side surface of the second lower electrode layer 312 and one side surface of the third mask pattern 343 may be positioned on the same plane. The first lower electrode layer 311, the second lower electrode layer 312, and the third lower electrode layer 313 can constitute the lower electrode 310.

A planarization process can be performed in the first direction DR1 on the second lower electrode material layer 312_P. For example, an etch back process may be used to remove the second lower electrode material layer 312_P.

Next, referring to FIG. 12, the first mask pattern 341, the second mask pattern 342, and the third mask pattern 343 can be removed. For example, an etching process may be used to remove the first mask pattern 341, the second mask pattern 342, and the third mask pattern 343. After the first mask pattern 341, the second mask pattern 342, and the third mask pattern 343 are removed, the dielectric layer 320 and the upper electrode 330 can be formed on the lower electrode 310.

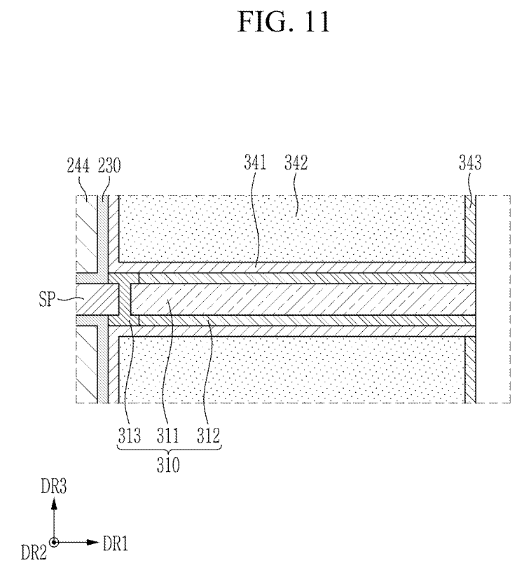

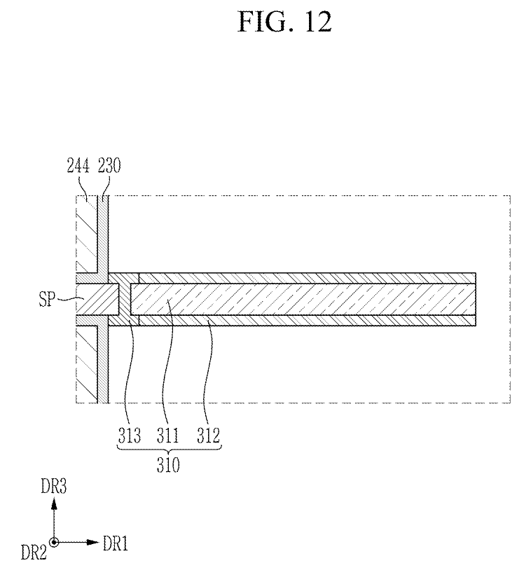

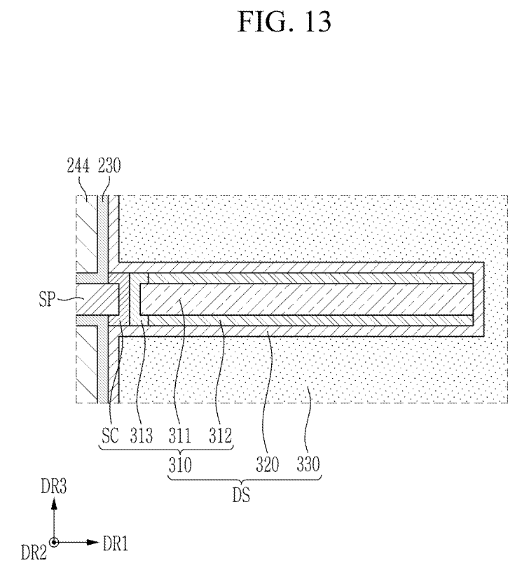

FIG. 13 is a cross-sectional view of a semiconductor device according to another embodiment. Descriptions of parts that are substantially the same as the previous example will be omitted, and explanations will be focused on the differences.

The lower electrode 310 of the semiconductor device according to one embodiment may further include a silicide layer SC.

The silicide layer SC can be positioned on the other side of the semiconductor pattern SP. The silicide layer SC can cover part of the other side surface and upper and lower surfaces of the semiconductor pattern SP. The silicide layer SC can cover the other end of a semiconductor pattern SP. The silicide layer SC may be positioned between the semiconductor pattern SP and the third lower electrode layer 313. The silicide layer SC may be positioned between the second insulating layer 230 and the third lower electrode layer 313. The silicide layer SC may be surrounded by the dielectric layer 320. A portion of the silicide layer SC may be in contact with the second insulating layer 230. The silicide layer SC can play a role in reducing the contact resistance between the lower electrode 310 and the semiconductor pattern SP.

The silicide layer SC may include a silicon metal compound. The silicide layer SC may include, for example, a compound in which silicon (Si) and at least one of titanium (Ti), cobalt (Co), and nickel (Ni) are combined. The silicide layer SC may include, for example, titanium silicide (TiSiₓ).

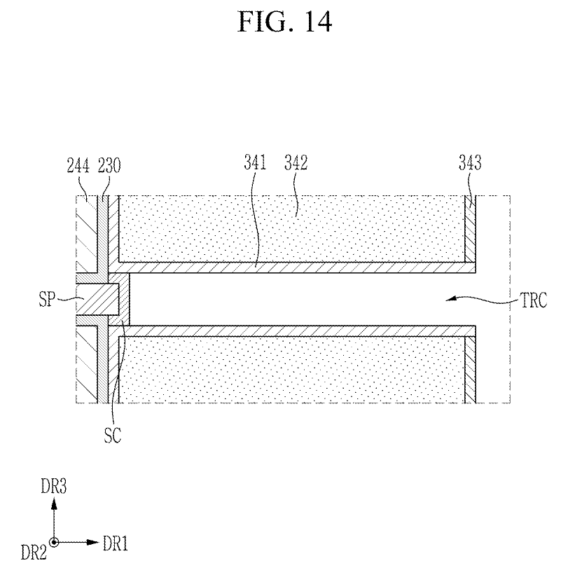

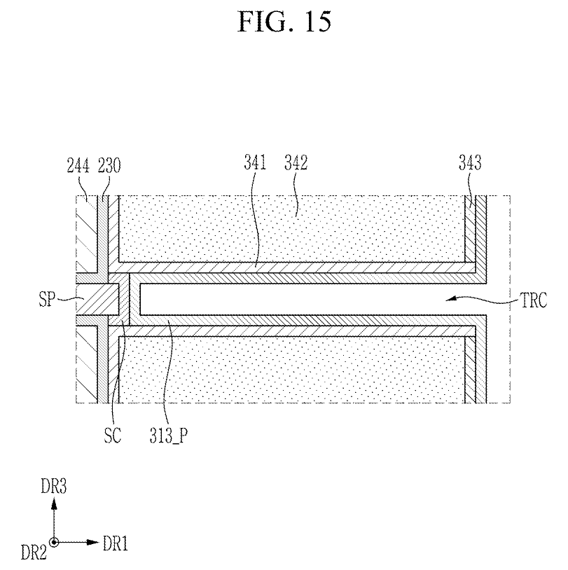

FIG. 14 and FIG. 15 are drawings showing a part of a method for manufacturing a semiconductor device according to another embodiment of FIG. 13. Some of the overlapping processes in the method for manufacturing a semiconductor device according to the previous embodiment are omitted, and the differences are mainly explained.

Referring to FIG. 14, the silicide layer SC may be formed on a portion of the semiconductor pattern SP protruding from the second spacer 244 and the second insulating layer 230. The silicide layer SC can be positioned within the trench TRC.

For example, the silicide layer SC can be formed by forming an additional silicon (Si) layer using the selective epitaxial growth (SEG) method, forming a metal layer thereon, and then performing an annealing process. However, without being limited thereto, a part of the semiconductor pattern SP may be converted into the silicide layer SC, such as by forming a metal layer on the semiconductor pattern SP without forming an additional silicon layer, and then performing an annealing process.

Next, referring to FIG. 15, the third lower electrode material layer 313_P can be formed within the trench TRC. The third lower electrode material layer 313_P can be formed on the silicide layer SC, the first mask pattern 341, and the third mask pattern 343. Thereafter, the third lower electrode layer 313 can be formed through a patterning process in which a portion of the third lower electrode material layer 313_P is removed.

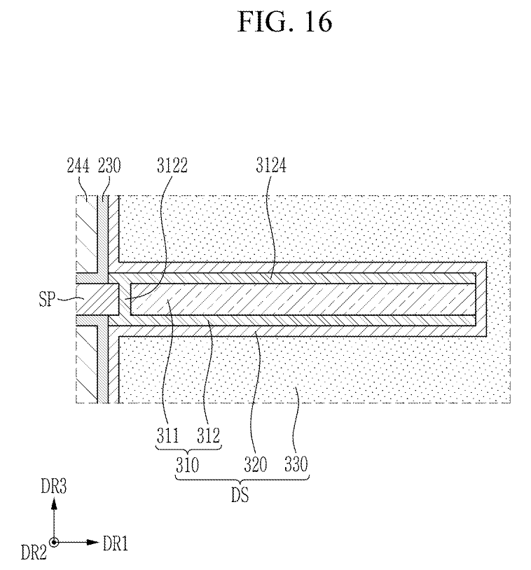

FIG. 16 is a cross-sectional view of a semiconductor device according to another embodiment. Descriptions of parts that are substantially the same as those described previously will be omitted, and differences will be mainly explained.

The semiconductor device according to one embodiment may include the data storage element DS positioned on the other side of the semiconductor pattern SP. The data storage element DS may include the lower electrode 310, the dielectric layer 320, and the upper electrode 330.

The lower electrode 310 may include the first lower electrode layer 311 and the second lower electrode layer 312.

The first lower electrode layer 311 may be surrounded by the second lower electrode layer 312. The first lower electrode layer 311 may have a rod shape extending in the first direction DR1. The first lower electrode layer 311 can be aligned parallel to the semiconductor pattern SP in the first direction DR1. The first lower electrode layer 311 can be positioned spaced apart from the semiconductor pattern SP with the second lower electrode layer 312 interposed therebetween.

The second lower electrode layer 312 may include a vertical portion 3122 extending in the third direction DR3 and a horizontal portion 3124 extending in the first direction DR1. The second lower electrode layer 312 including the vertical portion 3122 and the horizontal portion 3124 may have a cylindrical shape including an internal space. The first lower electrode layer 311 can be positioned in the internal space of the second lower electrode layer 312. The outer side of the second lower electrode layer 312 may be surrounded by the dielectric layer 320.

The vertical portion 3122 may be positioned between the semiconductor pattern SP and the first lower electrode layer 311. The vertical portion 3122 can be in contact with the other side surface of the semiconductor pattern SP. The vertical portion 3122 may be in contact with one side surface of the first lower electrode layer 311. The vertical portion 3122 may be positioned to overlap the semiconductor pattern SP in the first direction DR1. The vertical portion 3122 can be positioned to overlap the first lower electrode layer 311 in the first direction DR1.

The horizontal portion 3124 may be positioned between the first lower electrode layer 311 and the dielectric layer 320. The horizontal portion 3124 may have a shape surrounding the first lower electrode layer 311. The horizontal portion 3124 can be positioned to surround the other end of the semiconductor pattern SP. For example, the horizontal portion 3124 may cover part of the upper and lower surfaces of the semiconductor pattern SP. The horizontal portion 3124 may have a shape surrounding the other end of the semiconductor pattern SP. The horizontal portion 3124 can be positioned to overlap the first lower electrode layer 311 in the second direction DR2 and the third direction DR3. The horizontal portion 3124 can be formed conformally on the first lower electrode layer 311. The length of the horizontal portion 3124 in the first direction DR1 may be longer than the length of the first lower electrode layer 311, but is not limited thereto.

For example, the second lower electrode layer 312 may include internal spaces positioned on opposite sides in the first direction DR1. An end of a semiconductor pattern SP may be positioned in one internal space of the second lower electrode layer 312, and the first lower electrode layer 311 may be positioned in the other internal space of the second lower electrode layer 312.

The other side surface of the second lower electrode layer 312 may be positioned on the same plane as the other side surface of the first lower electrode layer 311. The other side surface of the horizontal portion of the second lower electrode layer 312 can be positioned on the same plane as the other side surface of the first lower electrode layer 311.

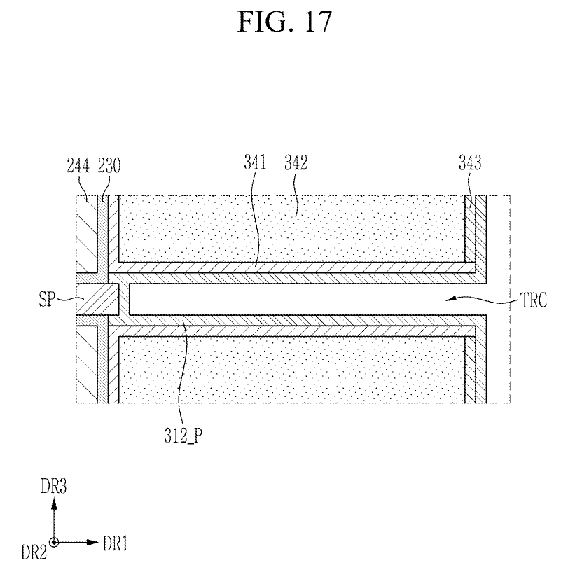

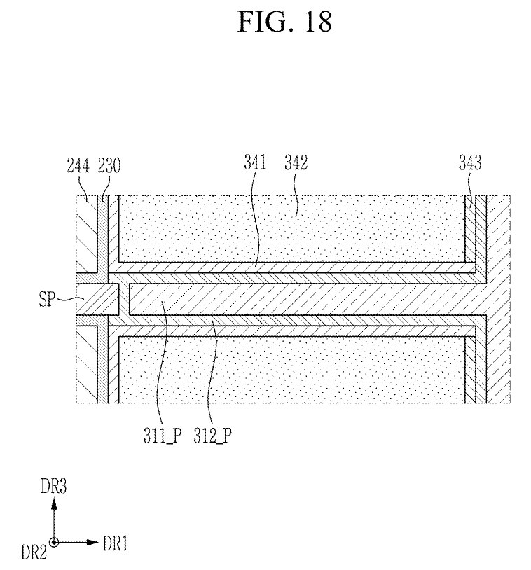

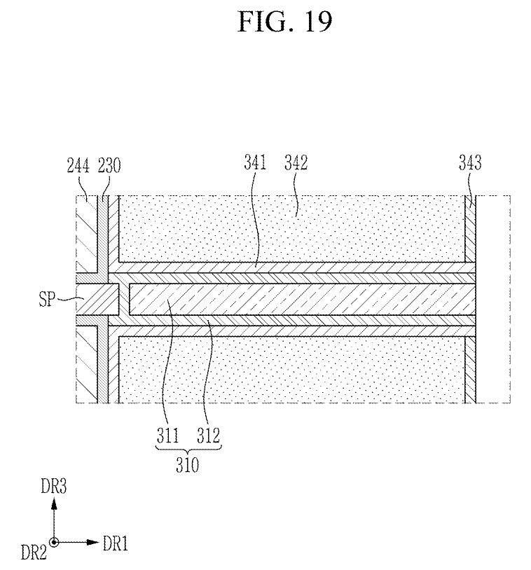

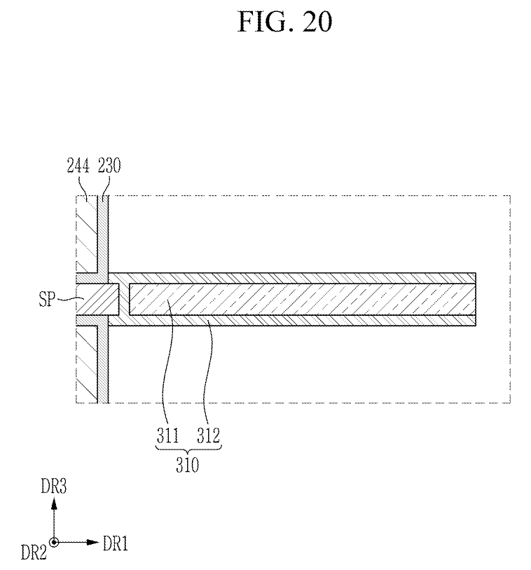

FIG. 17 to FIG. 20 are drawings showing a part of a method for manufacturing a semiconductor device according to another embodiment of FIG. 16. Descriptions of parts that are substantially the same as the manufacturing methods of the previously described embodiments will be omitted, and descriptions will be focused on the differences.

Referring to FIG. 17, the second lower electrode material layer 312_P can be formed within the trench TRC. The second lower electrode material layer 312_P can be conformally formed on the third mask pattern 343, the first mask pattern 341, and the semiconductor pattern SP. The second lower electrode material layer 312_P can be in contact with the other side surface of the semiconductor pattern SP and can cover a portion of the upper and lower surfaces of the semiconductor pattern SP. The second lower electrode material layer 312_P may have a form that surrounds the other end of the semiconductor pattern SP.

Next, referring to FIG. 18, the first lower electrode material layer 311_P can be formed within the trench TRC. The first lower electrode material layer 311_P can be formed on the second lower electrode material layer 312_P. The first lower electrode material layer 311_P can fill the inside of the trench TRC.

Next, referring to FIG. 19, a part of the first lower electrode material layer 311_P may be removed to form the first lower electrode layer 311, and a part of the second lower electrode material layer 312_P may be removed to form the second lower electrode layer 312. The first lower electrode layer 311 and the second lower electrode layer 312 can form the lower electrode 310. The first lower electrode material layer 311_P and the second lower electrode material layer 312_P can be partially removed through a planarization process. The planarization process of the first lower electrode material layer 311_P and the second lower electrode material layer 312_P can be performed in the first direction DR1.

Next, referring to FIG. 20, the first mask pattern 341, the second mask pattern 342, and the third mask pattern 343 can be removed. After that, the dielectric layer 320 and the upper electrode 330 can be additionally formed to form the data storage element DS.

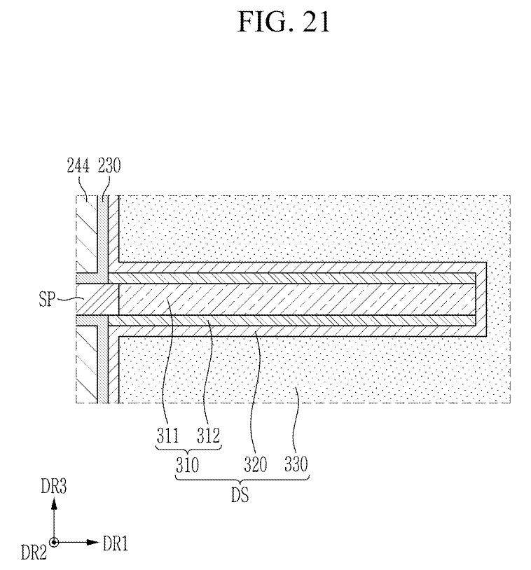

FIG. 21 is a cross-sectional view of a semiconductor device according to another embodiment. Descriptions of parts that are substantially the same as those described previously will be omitted, and differences will be mainly explained.

Referring to FIG. 21, the semiconductor device according to one embodiment may include the data storage element DS positioned on the other side of the semiconductor pattern SP. The data storage element DS may include the lower electrode 310, the dielectric layer 320, and the upper electrode 330.

The lower electrode 310 may include the first lower electrode layer 311 and the second lower electrode layer 312.

The first lower electrode layer 311 may be positioned on the other side of the semiconductor pattern SP. The first lower electrode layer 311 can be in contact with the semiconductor pattern SP. The first lower electrode layer 311 can be in contact with the other side surface of the semiconductor pattern SP. The first lower electrode layer 311 can be aligned parallel to the semiconductor pattern SP in the first direction DR1.

The second lower electrode layer 312 may have a shape extending in the first direction DR1. The second lower electrode layer 312 can be positioned on the semiconductor pattern SP and the first lower electrode layer 311. The second lower electrode layer 312 may have a shape that surrounds the other end of the semiconductor pattern SP and the first lower electrode layer 311.

The second lower electrode layer 312 can be positioned to overlap the first lower electrode layer 311 in the second direction DR2 and the third direction DR3. For example, the second lower electrode layer 312 may be positioned so as not to overlap the first lower electrode layer 311 in the first direction DR1, but is not limited thereto. The second lower electrode layer 312 can be conformally placed on the first lower electrode layer 311. The length of the second lower electrode layer 312 in the first direction DR1 may be longer than the length of the first lower electrode layer 311 in the first direction DR1, but is not limited thereto. For example, the second lower electrode layer 312 may have a hollow column shape with opposite sides open in the first direction DR1, but is not limited thereto. The first lower electrode layer 311 and the other end of the semiconductor pattern SP can be positioned in the inner empty space of the second lower electrode layer 312. The outer side of the second lower electrode layer 312 may be surrounded by the dielectric layer 320.

The other side surface of the second lower electrode layer 312 may be positioned on the same plane as the other side surface of the first lower electrode layer 311.

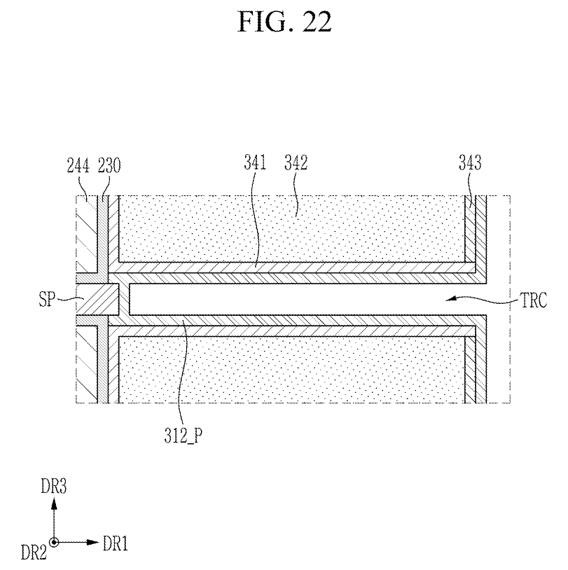

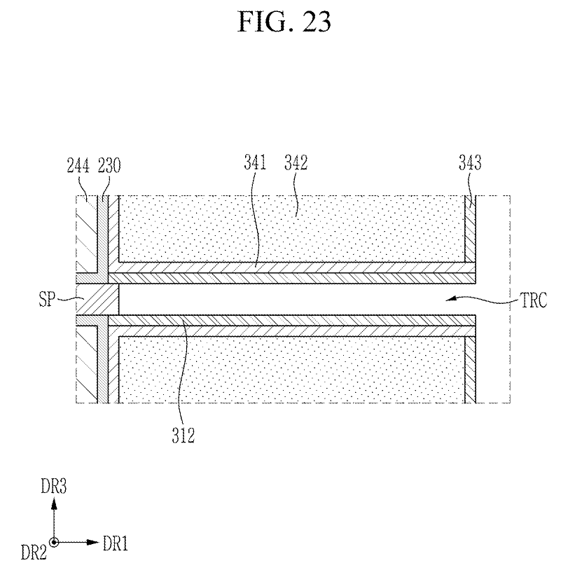

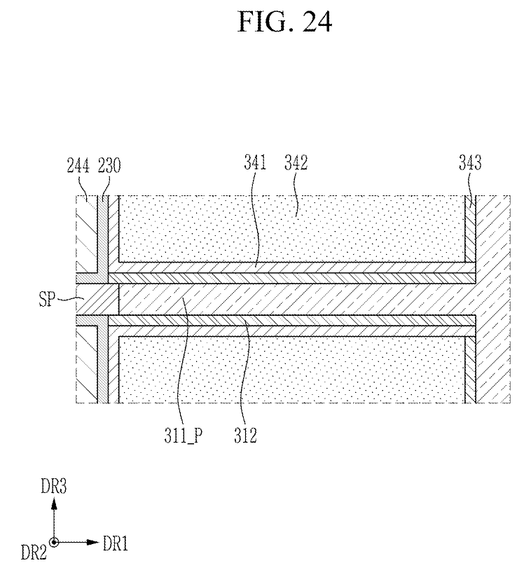

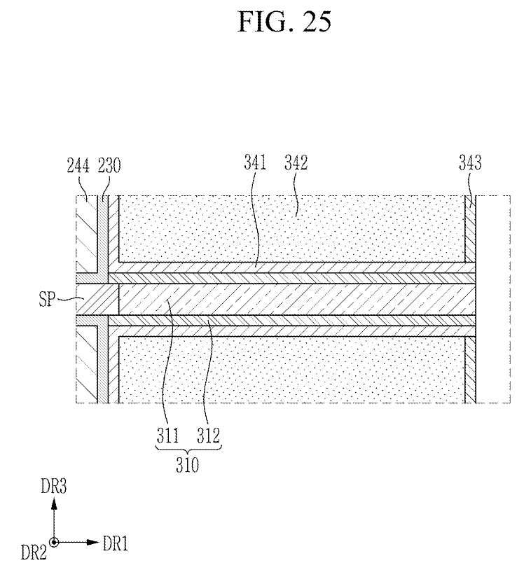

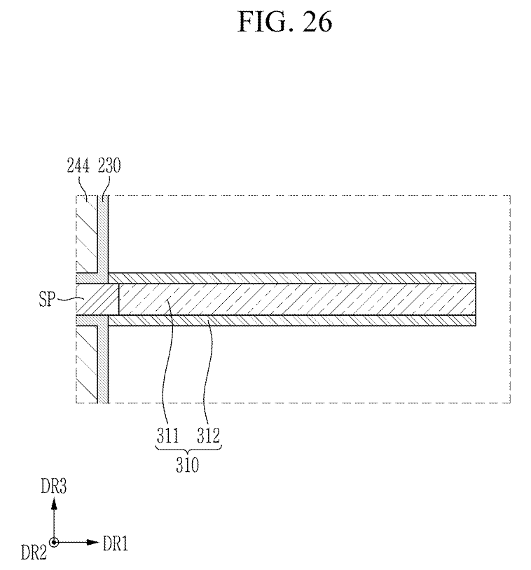

FIG. 22 to FIG. 26 are drawings showing a part of a method for manufacturing a semiconductor device according to another embodiment of FIG. 21. Descriptions of parts that are substantially the same as the manufacturing methods of the previously described embodiments will be omitted, and descriptions will be focused on the differences.

Referring to FIG. 22, the second lower electrode material layer 312_P can be formed within the trench TRC. The second lower electrode material layer 312_P can be conformally formed on the third mask pattern 343, the first mask pattern 341, and the semiconductor pattern SP. The second lower electrode material layer 312_P can be in contact with the other side surface of the semiconductor pattern SP and can cover a portion of the upper and lower surfaces of the semiconductor pattern SP. The second lower electrode material layer 312_P may have a form that surrounds the other end of the semiconductor pattern SP.

Next, referring to FIG. 23, a portion of the second lower electrode material layer 312_P may be removed to form the second lower electrode layer 312. A portion of the second lower electrode material layer 312_P that is on the third mask pattern 343 and a portion that is on the other side surface of the semiconductor pattern SP can be removed. The second lower electrode layer 312 may be positioned on the first mask pattern 341. Additionally, the second lower electrode layer 312 may partially overlap with the semiconductor pattern SP in the third direction DR3.

Next, referring to FIG. 24, the first lower electrode material layer 311_P can be formed within the trench TRC. Additionally, the first lower electrode material layer 311_P can be formed on the third mask pattern 343. The first lower electrode material layer 311_P can be in contact with the other side surface of the semiconductor pattern SP.

Next, referring to FIG. 25, a portion of the first lower electrode material layer 311_P may be removed to form the first lower electrode layer 311. A portion of the first lower electrode material layer 311_P positioned on the third mask pattern 343 can be removed. Additionally, a portion of the first lower electrode material layer 311_P that overlaps the trench TRC in the first direction DR1 can be removed.

Next, referring to FIG. 26, the first mask pattern 341, the second mask pattern 342, and the third mask pattern 343 can be removed. After the first mask pattern 341, the second mask pattern 342, and the third mask pattern 343 are removed, the dielectric layer 320 and the upper electrode 330 can be formed on the lower electrode 310.

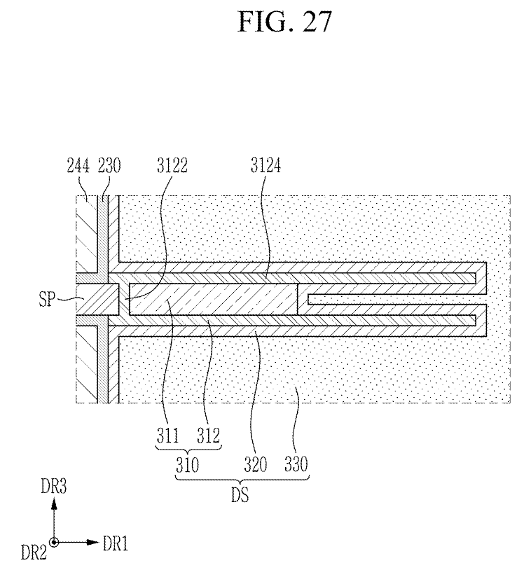

FIG. 27 is a cross-sectional view of a semiconductor device according to another embodiment. Descriptions of parts that are substantially the same as those described previously will be omitted, and differences will be mainly explained.

The semiconductor device according to one embodiment may include the data storage element DS positioned on the other side of the semiconductor pattern SP. The data storage element DS may include the lower electrode 310, the dielectric layer 320, and the upper electrode 330.

The lower electrode 310 may include the first lower electrode layer 311 and the second lower electrode layer 312.

The first lower electrode layer 311 may be surrounded by the second lower electrode layer 312. The first lower electrode layer 311 may have a rod shape extending in the first direction DR1.

The second lower electrode layer 312 may include the vertical portion extending in the third direction DR3 and the horizontal portion extending in the first direction DR1.

The vertical portion 3122 may be positioned between the semiconductor pattern SP and the first lower electrode layer 311. The vertical portion 3122 can be in contact with the other side surface of the semiconductor pattern SP. The horizontal portion 3124 may be positioned between the first lower electrode layer 311 and the dielectric layer 320. The horizontal portion 3124 may have a shape surrounding the first lower electrode layer 311. The horizontal portion 3124 can cover part of the upper and lower surfaces of the semiconductor pattern SP. The horizontal portion 3124 may have a shape surrounding the other end of the semiconductor pattern SP.

The other side surface of the second lower electrode layer 312 may not be positioned on the same plane as the other side surface of the first lower electrode layer 311. The length of the first lower electrode layer 311 in the first direction DR1 may be shorter than the length of the second lower electrode layer 312 in the first direction DR1. The length of the first lower electrode layer 311 in the first direction DR1 may be shorter than the length of the horizontal portion 3124 of the second lower electrode layer 312 in the first direction DR1. The other side surface of the first lower electrode layer 311 can be positioned within the second lower electrode layer 312. Since the other side surface of the first lower electrode layer 311 is positioned within the second lower electrode layer 312, the lower electrode 310 may have a cylindrical shape.

The dielectric layer 320 and the upper electrode 330 may be positioned on the lower electrode 310. At least a portion of the dielectric layer 320 may be positioned on the inner side of the second lower electrode layer 312. The dielectric layer 320 can be positioned between the horizontal portions 3124 of the second lower electrode layer 312. At least a portion of the upper electrode 330 may be positioned on the inner side of the second lower electrode layer 312. The upper electrode 330 may be positioned between the horizontal portions 3124 of the second lower electrode layer 312.

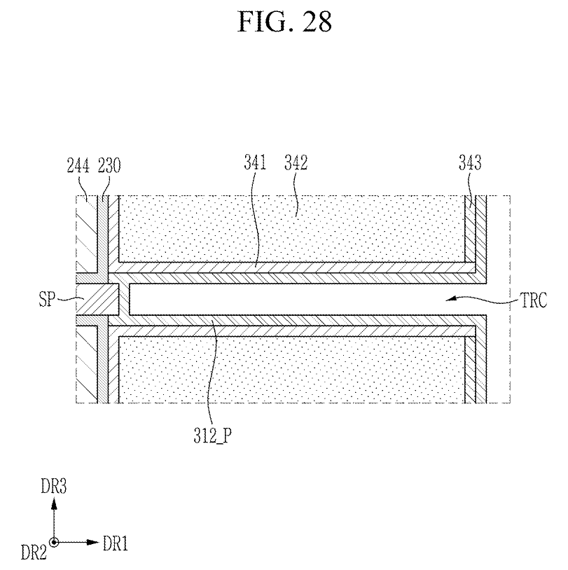

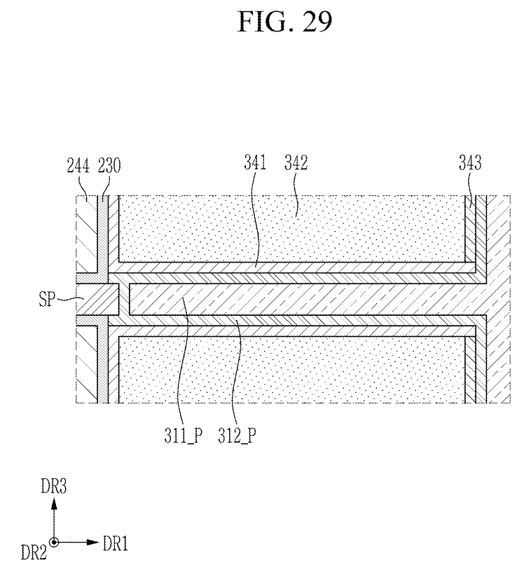

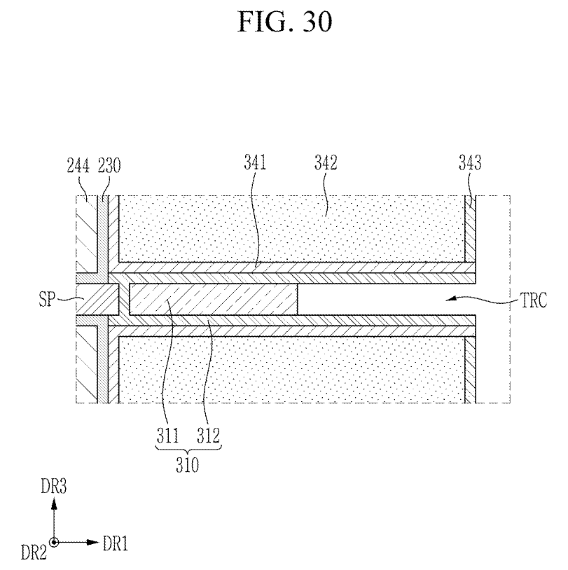

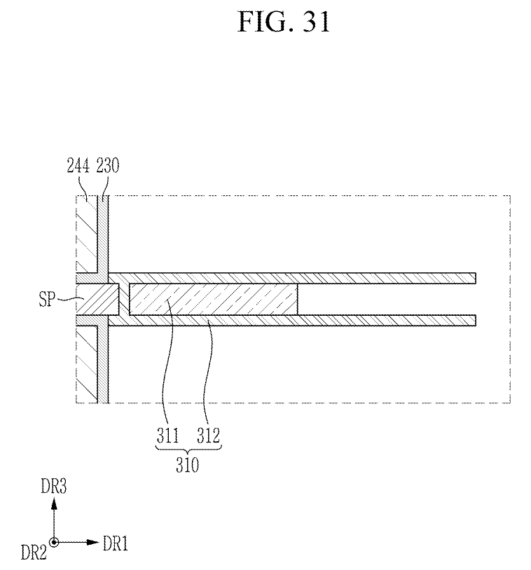

FIG. 28 to FIG. 31 are drawings showing a part of a method for manufacturing a semiconductor device according to another embodiment of FIG. 27. Descriptions of parts that are substantially the same as the manufacturing methods of the previously described embodiments will be omitted, and descriptions will be focused on the differences.

Referring to FIG. 28, the second lower electrode material layer 312_P can be formed within the trench TRC. The second lower electrode material layer 312_P can be conformally formed on the third mask pattern 343, the first mask pattern 341, and the semiconductor pattern SP. The second lower electrode material layer 312_P can be in contact with the other side surface of the semiconductor pattern SP and can cover a portion of the upper and lower surfaces of the semiconductor pattern SP. The second lower electrode material layer 312_P may have a form that surrounds the other end of the semiconductor pattern SP.

Next, referring to FIG. 29, the first lower electrode material layer 311_P can be formed within the trench TRC. The first lower electrode material layer 311_P can be formed on the second lower electrode material layer 312_P. The first lower electrode material layer 311_P can fill the inside of the trench TRC.

Next, referring to FIG. 30, a portion of the first lower electrode material layer 311_P and the second lower electrode material layer 312_P may be removed to form the first lower electrode layer 311 and the second lower electrode layer 312.

The second lower electrode material layer 312_P may have a portion positioned over the third mask pattern 343 removed. A portion of the first lower electrode material layer 311_P positioned on the third mask pattern 343 and a certain portion of the first lower electrode material layer 311_P positioned in the trench TRC may be removed. As a portion of the first lower electrode material layer 311_P positioned within the trench TRC is removed, the other side surface of the first lower electrode layer 311 can be positioned within the second lower electrode layer 312.

Next, referring to FIG. 31, the first mask pattern 341, the second mask pattern 342, and the third mask pattern 343 can be removed. After the first mask pattern 341, the second mask pattern 342, and the third mask pattern 343 are removed, the dielectric layer 320 and the upper electrode 330 can be formed on the lower electrode 310.

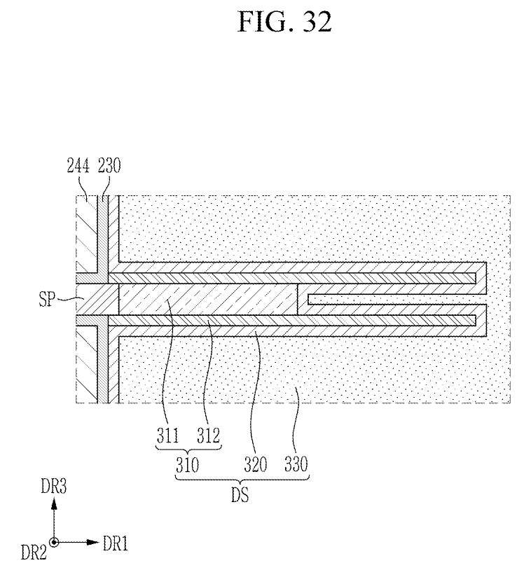

FIG. 32 is a cross-sectional view of a semiconductor device according to another embodiment. Descriptions of parts that are substantially the same as those described previously will be omitted, and differences will be mainly explained.

The semiconductor device according to one embodiment may include the data storage element DS positioned on the other side of the semiconductor pattern SP. The data storage element DS may include the lower electrode 310, the dielectric layer 320, and the upper electrode 330.

The lower electrode 310 may include the first lower electrode layer 311 and the second lower electrode layer 312.

The first lower electrode layer 311 may be surrounded by the second lower electrode layer 312. The first lower electrode layer 311 may have a rod shape extending in the first direction DR1. The first lower electrode layer 311 can be in contact with the semiconductor pattern SP. The first lower electrode layer 311 can be in contact with the other side surface of the semiconductor pattern SP. The first lower electrode layer 311 can cover a portion of the upper and lower surfaces of the semiconductor pattern SP.

The second lower electrode layer 312 can be positioned on the semiconductor pattern SP and the first lower electrode layer 311. The second lower electrode layer 312 may have a shape that surrounds the first lower electrode layer 311.

The second lower electrode layer 312 can be positioned to overlap the first lower electrode layer 311 in the second direction DR2 and the third direction DR3. For example, the second lower electrode layer 312 may be positioned so as not to overlap the first lower electrode layer 311 in the first direction DR1, but is not limited thereto. The second lower electrode layer 312 may have a shape that protrudes in the first direction DR1 from the first lower electrode layer 311. For example, the second lower electrode layer 312 may have a hollow column shape with opposite sides open in the first direction DR1, but is not limited thereto. The first lower electrode layer 311 can be positioned in the inner empty space of the second lower electrode layer 312. The outer side of the second lower electrode layer 312 may be surrounded by the dielectric layer 320.

The other side surface of the second lower electrode layer 312 may not be positioned on the same plane as the other side surface of the first lower electrode layer 311. The length of the first lower electrode layer 311 in the first direction DR1 may be shorter than the length of the second lower electrode layer 312 in the first direction DR1. The other side surface of the first lower electrode layer 311 can be positioned within the second lower electrode layer 312. Since the other side surface of the first lower electrode layer 311 is positioned within the second lower electrode layer 312, the lower electrode 310 may have a cylindrical shape.

The dielectric layer 320 and the upper electrode 330 may be positioned on the lower electrode 310. The dielectric layer 320 may be positioned on the inner side of the second lower electrode layer 312. The upper electrode 330 may be positioned on the inner side of the second lower electrode layer 312.

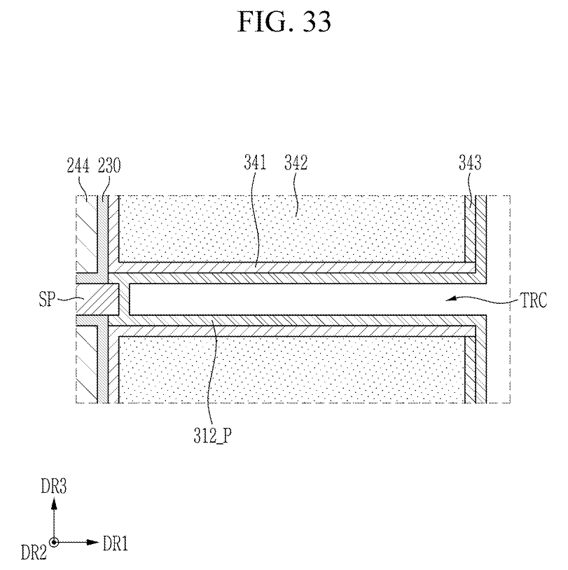

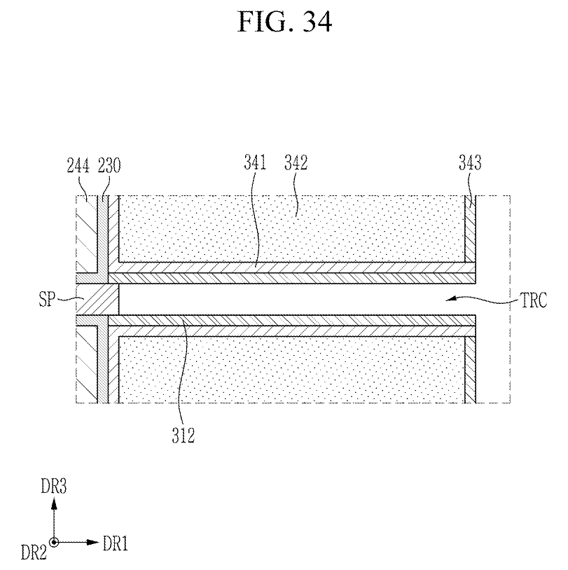

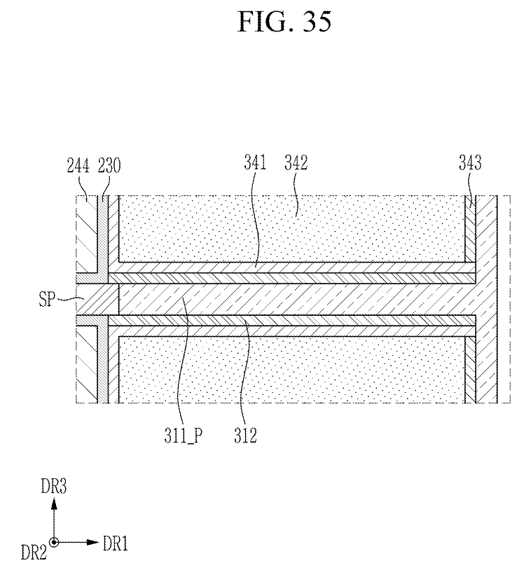

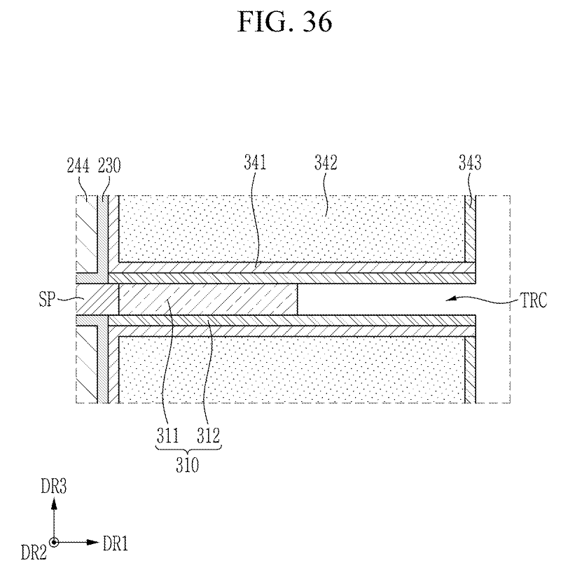

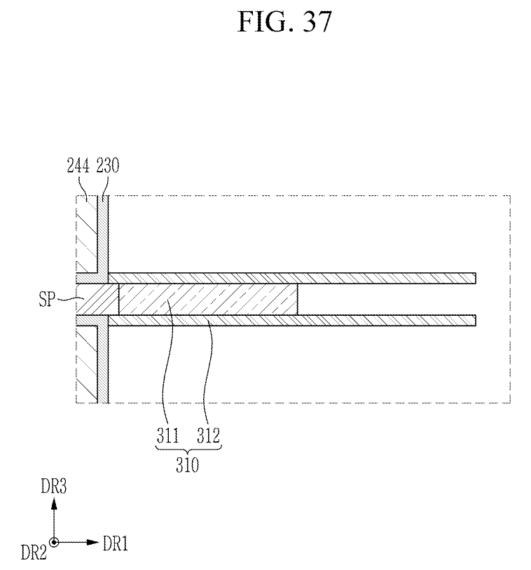

FIG. 33 to FIG. 37 are drawings showing a part of a method for manufacturing a semiconductor device according to another embodiment of FIG. 32. Descriptions of parts that are substantially the same as the manufacturing methods of the previously described embodiments will be omitted, and descriptions will be focused on the differences.

Referring to FIG. 33, the second lower electrode material layer 312_P can be formed within the trench TRC. The second lower electrode material layer 312_P can be conformally formed on the third mask pattern 343, the first mask pattern 341, and the semiconductor pattern SP. The second lower electrode material layer 312_P can be in contact with the other side surface of the semiconductor pattern SP and can cover a portion of the upper and lower surfaces of the semiconductor pattern SP. The second lower electrode material layer 312_P may have a form that surrounds the other end of the semiconductor pattern SP.

Next, referring to FIG. 34, a portion of the second lower electrode material layer 312_P may be removed to form the second lower electrode layer 312. A portion of the second lower electrode material layer 312_P that is on the third mask pattern 343 and a portion of the second lower electrode material layer 312_P that is on the other side surface of the semiconductor pattern SP can be removed. The second lower electrode layer 312 may be positioned on the first mask pattern 341. Additionally, the second lower electrode layer 312 may partially overlap with the semiconductor pattern SP in the third direction DR3.

Next, referring to FIG. 35, the first lower electrode material layer 311_P can be formed within the trench TRC. Additionally, the first lower electrode material layer 311_P can be formed on the third mask pattern 343. The first lower electrode material layer 311_P can be in contact with the other side surface of the semiconductor pattern SP.

Next, referring to FIG. 36, a portion of the first lower electrode material layer 311_P may be removed to form the first lower electrode layer 311. A portion of the first lower electrode material layer 311_P positioned on the third mask pattern 343 can be removed. Additionally, a portion of the first lower electrode material layer 311_P positioned within the trench TRC can be removed. As the portion positioned within the trench TRC of the first lower electrode material layer 311_P is removed, the other side surface of the first lower electrode layer 311 can be positioned within the second lower electrode layer 312.

Next, referring to FIG. 37, the first mask pattern 341, the second mask pattern 342, and the third mask pattern 343 can be removed. After the first mask pattern 341, the second mask pattern 342, and the third mask pattern 343 are removed, the dielectric layer 320 and the upper electrode 330 can be formed on the lower electrode 310.

Although the embodiments of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A semiconductor device comprising:
a substrate;
a semiconductor pattern positioned on the substrate and extending in a first direction parallel to an upper surface of the substrate;
a word line positioned on the semiconductor pattern and extending in a second direction, which is parallel to the upper surface of the substrate and intersects the first direction;
a bit line connected to a first end of the semiconductor pattern on a first side of the semiconductor pattern and extending in a third direction perpendicular to the upper surface of the substrate;
a lower electrode comprising a first lower electrode layer covering a second end of the semiconductor pattern and positioned on a second side of the semiconductor pattern, and a second lower electrode layer positioned on the first lower electrode layer;
an upper electrode positioned on the lower electrode; and
a dielectric layer positioned between the lower electrode and the upper electrode.

2. The semiconductor device of claim 1, wherein the lower electrode further comprises a third lower electrode layer positioned between the first lower electrode layer and the semiconductor pattern.

3. The semiconductor device of claim 2, wherein the third lower electrode layer covers the second end of the semiconductor pattern.

4. The semiconductor device of claim 2, wherein the third lower electrode layer comprises polysilicon.

5. The semiconductor device of claim 2, wherein the lower electrode further comprises a silicide layer positioned between the third lower electrode layer and the second end of the semiconductor pattern.

6. The semiconductor device of claim 1, wherein the first lower electrode layer comprises a low-resistance metal, and the second lower electrode layer comprises a high work function material.

7. The semiconductor device of claim 1, wherein the first lower electrode layer is in contact with a surface of the semiconductor pattern at the second side of the semiconductor pattern, and the second lower electrode layer surrounds the second end of the semiconductor pattern.

8. The semiconductor device of claim 1, wherein the second lower electrode layer comprises a vertical portion positioned between the first lower electrode layer and the semiconductor pattern and extending in the third direction and a horizontal portion extending in the first direction and surrounding an outer side of the first lower electrode layer.

9. The semiconductor device of claim 1, wherein a length of the first lower electrode layer in the first direction is shorter than a length of the second lower electrode layer in the first direction.

10. The semiconductor device of claim 1, wherein one side surface of the first lower electrode layer is positioned on the same plane as a side surface of the second lower electrode layer at the second side of the second lower electrode layer.

11. A semiconductor device comprising:
a substrate;
a semiconductor pattern positioned on the substrate and extending in a first direction parallel to an upper surface of the substrate;
a word line positioned on the semiconductor pattern and extending in a second direction, which is parallel to the upper surface of the substrate and intersects the first direction;
a bit line connected to a first end of the semiconductor pattern on a first side of the semiconductor pattern and extending in a third direction perpendicular to the upper surface of the substrate;
a lower electrode comprising a first lower electrode layer positioned on a second side of the semiconductor pattern, a second lower electrode layer positioned on the first lower electrode layer, and a third lower electrode layer positioned between the first lower electrode layer and the semiconductor pattern;
an upper electrode positioned on the lower electrode; and
a dielectric layer positioned between the lower electrode and the upper electrode.

12. The semiconductor device of claim 11, wherein the third lower electrode layer comprises polysilicon and covers a second end of the semiconductor pattern at the second side of the semiconductor pattern.

13. The semiconductor device of claim 12, wherein a silicide layer is positioned between the third lower electrode layer and the second end of the semiconductor pattern.

14. The semiconductor device of claim 11, wherein one side surface of the first lower electrode layer is positioned on the same plane as a side surface of the second lower electrode layer at the second side of the semiconductor pattern.

15. The semiconductor device of claim 11, wherein a length of the first lower electrode layer in the first direction is shorter than a length of the second lower electrode layer in the first direction.

16. A semiconductor device comprising:
a substrate;
a semiconductor pattern positioned on the substrate and extending in a first direction parallel to an upper surface of the substrate;
a word line positioned on the semiconductor pattern and extending in a second direction, which is parallel to the upper surface of the substrate and intersects the first direction;
a bit line connected to a first end of the semiconductor pattern on a first side of the semiconductor pattern and extending in a third direction perpendicular to the upper surface of the substrate;
a lower electrode comprising a first lower electrode layer connected to a second end of the semiconductor pattern and positioned on a second side of the semiconductor pattern, and a second lower electrode layer positioned on the first lower electrode layer and covering the second end of the semiconductor pattern;
an upper electrode positioned on the lower electrode; and
a dielectric layer positioned between the lower electrode and the upper electrode,
wherein the second lower electrode layer comprises a vertical portion positioned between the first lower electrode layer and the semiconductor pattern and extending in the third direction and a horizontal portion extending in the first direction and surrounding an outer side of the first lower electrode layer.

17. The semiconductor device of claim 16, wherein the first lower electrode layer comprises a low-resistance metal, and the second lower electrode layer comprises a high work function material.

18. The semiconductor device of claim 16, wherein a length of the first lower electrode layer in the first direction is shorter than a length of the second lower electrode layer in the first direction.

19. The semiconductor device of claim 16, wherein one side surface of the first lower electrode layer is positioned on the same plane as a side surface of the second lower electrode layer at the second side of the semiconductor pattern.

20. The semiconductor device of claim 16, wherein the lower electrode is positioned at the same level as the semiconductor pattern and is aligned parallel to the semiconductor pattern.
